(19) United States
(12) Patent Application Publication
(10) Pub. No.: US 2014/0224325 A1
(43) Pub. Date: Aug. 14, 2014

(54) Self-Contained Solar Power Unit

(71) Applicant: SOLARWORLD INDUSTRIES AMERICA, INC., Hillsboro, OR (US)

(72) Inventors: Nathan Stoddard, Beaverton, OR (US); Chris Stapelmann, Beaverton, OR (US)

(73) Assignee: SOLARWORLD INDUSTRIES AMERICA, INC., Hillsboro, OR (US)

(21) Appl. No.: 13/763,777

(22) Filed: Feb. 11, 2013

(51) Int. Cl. H01L 31/042

(52) U.S. Cl. CPC H01L 31/0422
USPC 136/259

(57) ABSTRACT

A solar power unit having a solar module with a frame defining a planar solar collection area, a photovoltaic cell mounted within said area, a junction box electrically connected to at least one of said photovoltaic cells; and a support structure fixable to said solar module having a first leg set comprising a first upper leg and a first lower leg, the leg set securing the solar module on a surface at an angle.

### TECHNICAL FIELD

Embodiments generally relate to photovoltaic power sources, and in particular to photovoltaic cell modules.

### BACKGROUND

Photovoltaic installations, for example those appropriate for the residential market, are often installed on residential rooftops or in similar installations. For example, the residential market for solar photovoltaic products typically involves at least: a house with a suitably inclined, non-shaded roof; a home owner willing to undergo a mid-level home renovation project involving contractors and roof penetrations; sufficient capital to cover the costs of the installation; and certain risk tolerance, for example in connection with the possibility of damage or a roof fire over the life of the installation.

A group of people fitting these requirements may generally be said to constitute the current residential market for solar panels, and even where all of the requirements are met, significant hurdles including the sourcing of materials and labor may be necessary to complete a solar installation project. Thus, the current residential market is likely to be significantly smaller than the total proportion of residential units whose occupants may have some interest in a photovoltaic installation, but who lack one or more of the exemplary requirements set forth above.

Attempt to broaden the appeal of photovoltaic installations to a wider segment of society have focused on simplifications to the racking, mounting and wiring to simplify roof top installation for the benefit, for example, of the certified installer. A further attempt has been the development of micro-inverters that allow each module to be controlled and monitored individually, delivering AC power directly from the roof top.

However, in addressing one or another barrier to entry, there has been no comprehensive solution to increasing the versatility of photovoltaic installations or broadening their appeal.

### SUMMARY

According to various embodiments, a solar power unit including a solar module is disclosed, the solar module defined by a framed, planar solar collection area with at least one photovoltaic cell mounted on the solar collection area and, for example, a junction box electrically connected to the cells.

A support structure is attachable or attached to the solar module. The support structure has at least one leg set having an upper leg and a lower leg. Because of the difference in height of the legs the leg set, the solar module can be secured on a surface at an angle.

According to an aspect of the disclosure, the solar power unit may have at least one hinge for fixing a leg set to the solar module. Additionally, the hinge may allow the leg set to rotate on said first hinge on a first axis parallel to a first side of said frame, for example, the leg set may be rotated from a working position to a flat storage position, such as under the module, depending upon the orientation of the hinge.

According to a further aspect of the disclosure, the support structure may have a second leg set working in conjunction with the first leg set. For example, the second leg set may also include an upper leg and a lower leg, as in the first leg set, the leg sets cooperating to secure the solar module on a surface at an angle.

In such a case, a second hinge may be provided for the second leg set, fixing the second leg set, for example to the frame, for rotating the second leg set under the solar power unit. The hinge for the second leg set may then advantageously be oriented generally parallel to the hinge of the first leg set. In operation, the hinges define axes of rotation of their respective leg sets, permitting rotation from an orientation parallel with the plane of the solar collection area to an orientation perpendicular therewith (and/or, depending on sun angle, parallel to the orientation of incoming solar rays.

According to the present invention the junction box is any kind of electrical connection point connecting the electrical contacts from the module laminate to the external wiring and may include micro inverters, switches, sensors, terminal blocks, bypass diodes and the like or can simply provide electric terminals without bypass diodes.

According to a further aspect of the disclosure, the solar power unit may include a micro-inverter connected to or incorporated in a junction box.

According to a further aspect of the present disclosure, the solar power unit may include a rod or similar contact means for providing electrical soil grounding, the rod contacting a soil surface. The rod may be secured to a leg set, the leg set acting as the grounding means.

According to various embodiments, a support structure rotatably hinged to the solar module having a first and second leg set each having a first upper leg height and a first lower leg height may secure the module to a surface at an angle. The first and second leg sets may each have a unitary structure.

According to an aspect of the disclosure, the unitary structure of each leg set may take a generally convex quadrilateral shape, defined by a first height corresponding to what is referred to as a first and/or second upper leg height and a second height corresponding what is referred to as a first and/or second lower leg height, respectively. Advantageously, the first and second upper leg heights may be the same, and the first and second lower leg heights may be the same.

According to a further aspect of the disclosure, the solar power units may include connectors to link multiple units together.

According to a further aspect of the disclosure, the first and second leg sets may include a securing port for receiving a means for fixing the leg sets to each other. Advantageously, a rigid rod or beam may be used for this purpose, the port having a shape and/or dimension adapted to receive the fixing means.

According to a further aspect of the disclosure, the solar power unit may be adjustable to permit the solar module to be oriented at multiple angles relative to the surface. Moreover, the legs may be folded and snapped into place.

### BRIEF DESCRIPTION OF THE DRAWINGS

In the drawings, like reference characters generally refer to the same parts throughout the different views. The drawings are not necessarily to-scale, instead generally being intent upon illustrating the principles of various embodiments. In the following descriptions, various embodiments are described with reference to the following drawings, in which:

FIGS. 1A and 1B are plan views of the rear and side view, respectively, of an embodiment of the present disclosure.

FIGS. 2A and 2B are plan views of the rear and side view, respectively, of an embodiment of the present disclosure.

FIGS. 3A and 3B are plan views of the rear and side view respectively, of an embodiment of the present disclosure.

FIGS. 4A and 4B are plan views of the rear and side view, respectively, of an embodiment of the present disclosure.

FIG. 5A illustrates a side plan view of an embodiment of the present disclosure.

FIG. 5B illustrates a side plan view of an alternate embodiment of the present disclosure.

FIG. 5C illustrates a cross-sectional plan view of a fastener of the present disclosure.

FIG. 6 is a perspective view of an embodiment of the present disclosure.

FIG. 7 illustrates a side plan view of an embodiment of the present disclosure.

FIG. 8 is a perspective view of an embodiment of the present disclosure.

FIGS. 9A-C are perspective views of respective exemplary component parts of an embodiment of the present disclosure.

### DESCRIPTION

The following detailed description refers to the accompanying drawings that show, by way of illustration, specific detail and embodiments in which the invention may be practiced. These embodiments are described in sufficient detail to enable those skilled in the art to practice the embodiments as disclosed. Other embodiments may be utilized and structural, logical, and electrical changes may be made without departing from the scope of the invention. The various embodiments are not necessarily mutually exclusive as some embodiments can be combined with one or more other embodiments to form new embodiments. In the context of this description, the terms “connected” and “coupled” are used to describe both a direct and an indirect connection and a direct or indirect coupling. In the figures, identical or similar elements are provided with identical reference symbols insofar as this is expedient.

Various exemplary embodiments provide a self-contained solar power unit with a built-in support system providing tilt, ground anchoring and an AC micro-inverter connected to wiring that can either plug directly into a suitable mains outlet, or can be wired into the circuit breaker box of a residence.

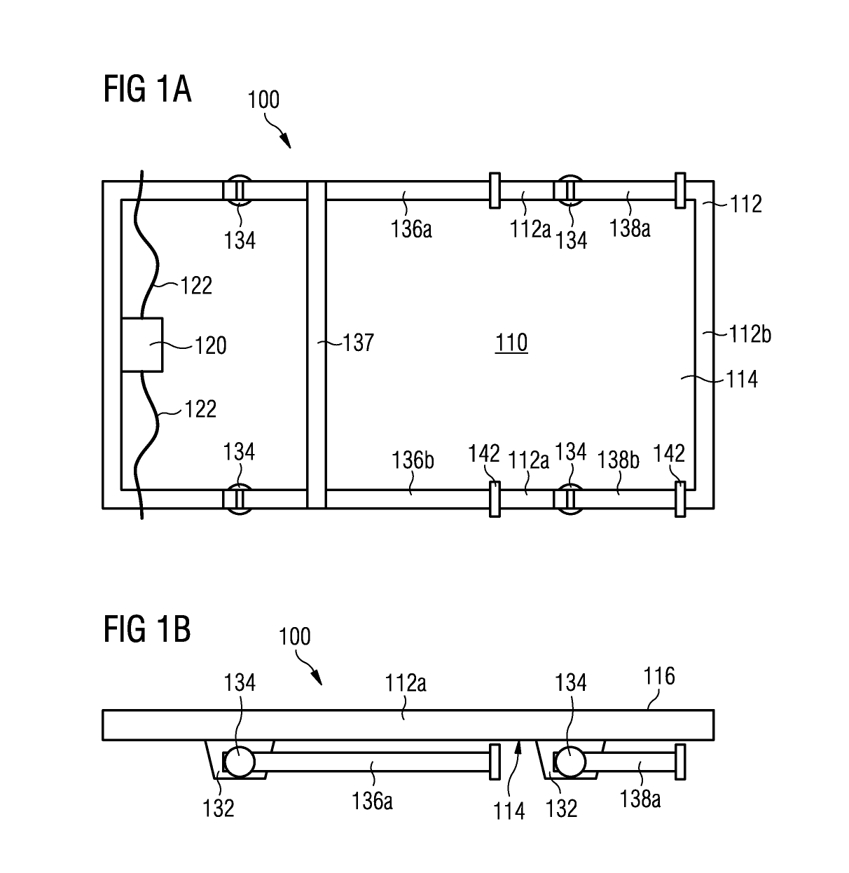

FIGS. 1A and 1B illustrate an exemplary embodiment of the self-contained solar power unit of the present disclosure. In particular, FIG. 1A illustrates solar power unit 100 showing the rear face of a solar module 110. Solar module 110 is formed of a frame 112 defining a solar collection area. In particular, the solar collection area is shown as back sheet 114, which may be supported in and by frame 112. In general solar collection area/back sheet 114 is typically planar, and often rectangular in shape.

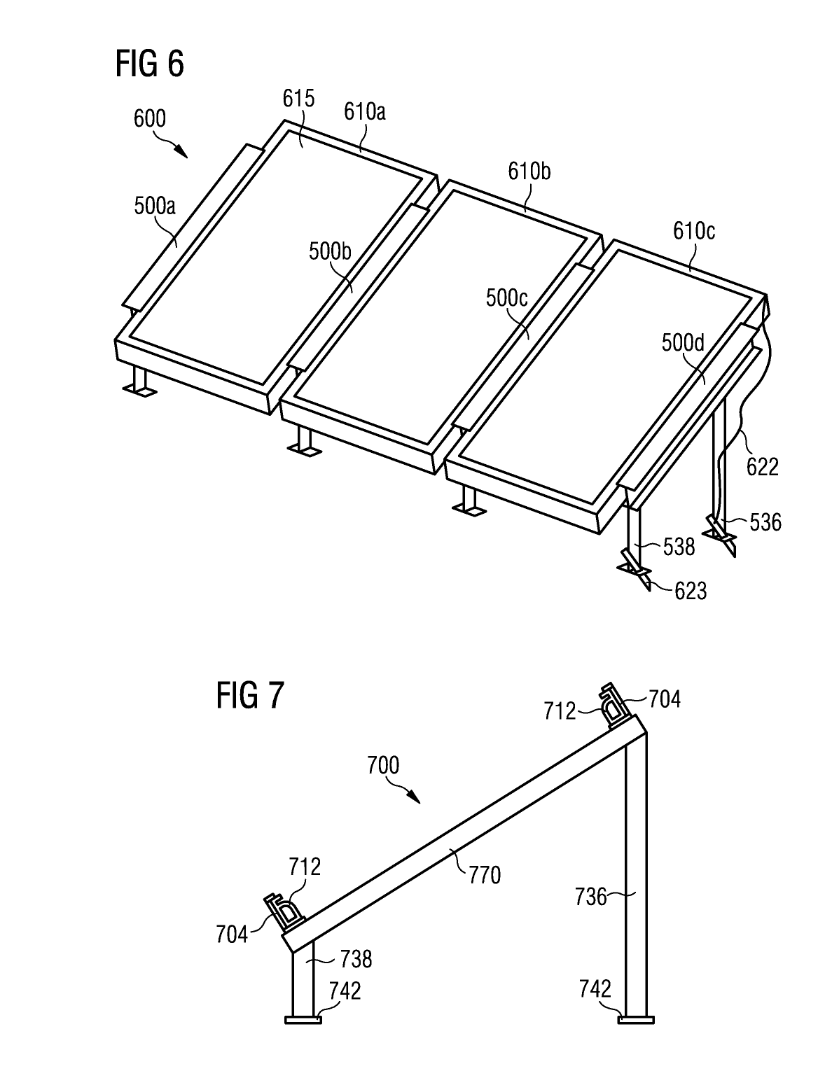

Module 110, as well as any solar module disclosed in connection with the embodiments described herein may advantageously be any one of a number of well-known solar modules having a plurality of solar cells (shown e.g. in FIG. 6) mounted on or integral with the front side (116, FIG. 1B) thereof, the solar cells being any one of a crystalline, poly-crystalline, amorphous silicon or other suitable material, or any other photovoltaic cell adapted to be mounted within the solar collection area occupied by back sheet 114.

Junction box/micro-inverter 120, physically secured to frame 112 and/or back sheet 114, is electrically connected to one or more solar cells mounted on/forming part of solar module 110. Junction box/micro-inverter 120 may advantageously include electrical contacts and/or an AC micro-inverter. Ground wires 122 are shown extending from junction box/micro-inverter 120. Alternately, junction box/micro-inverter 120 may be mounted as separate components to frame 112 or back sheet 114 with an electrical connection (not shown) in between.

FIG. 1B shows solar power unit 100 from a side thereof. In particular, hinge plates 132 are shown extending away from frame 112 downward and away from back sheet 114 of module 110. For example, long side 112a of frame 112 may be integral with hinge plates 132, the hinge plates being formed of the same material, for example a metal or rigid plastic. Alternately, hinge plates 132 may be formed separately and attached to frame 112, in particular, and for example, long side 112a by fasteners, welded or may be fixed thereto by adhesive. Hinge plate 132 may also be formed integrally with frame 112.

Legs 136a-b and 138a-b are shown pivotably mounted to hinge plates 132 by hinge pins 134 at a first end, and terminated in foot pads 142 at a second end. FIGS. 1A and 1B show legs 136 and 138 respectively positioned adjacent to and parallel with frame 112, in particular long frame sides 112a. This configuration, which may be referred to as the closed, retracted, or flat shipping position, illustrates solar unit 100 in compacted form. In this configuration, FIG. 1a illustrates cross bar 137 which cross bar may connect legs 136a and 136b to one another. Legs 136a and 138a form a first leg set, wherein one leg (136a) is longer than the other (138a). Likewise, legs 136b and 138b form a second leg set, as described in further detail below.

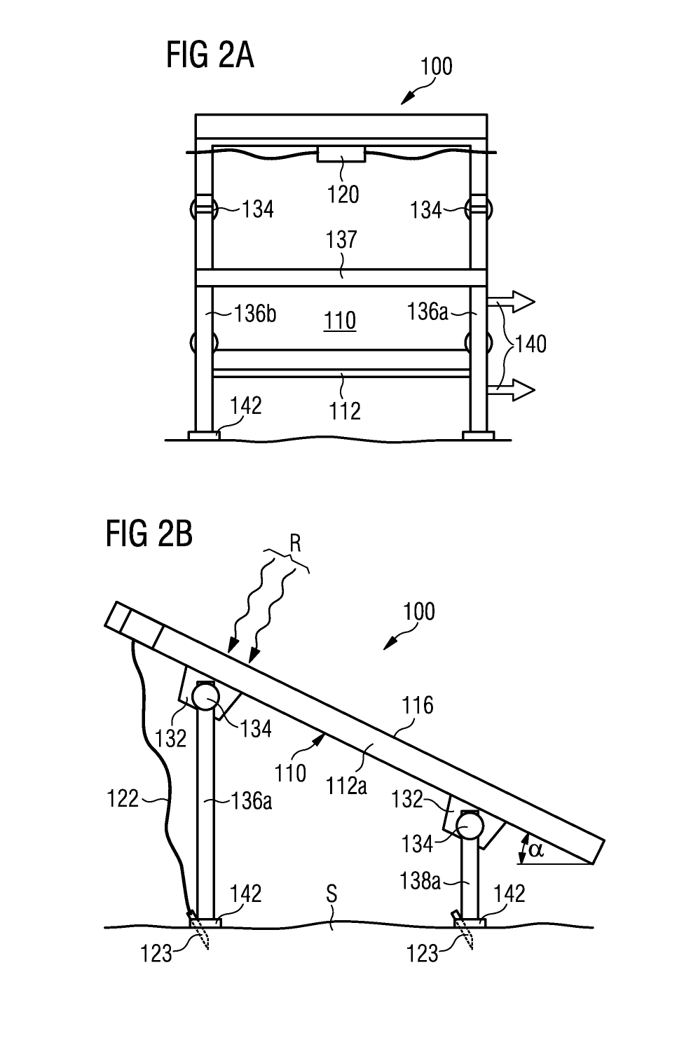

FIGS. 2A and 2B show solar power unit 100 in an operational configuration. In particular, legs 136a-b and 138a-b are shown rotated, or pivoted, about hinge pins 134. Advantageously, each of legs 136a-b (which move as a single unit due to cross bar 137) and 138a-b are respectively shown rotated such that foot pads 142 are generally parallel to a surface S, which may be a generally planar surface, such as a sidewalk, lawn, deck or field, on which solar power unit 100 may be placed.

Accordingly, the first leg set (136a/138a) and the second leg set (136b/138b) are shown deployed to support module 110 on surface S. As shown in FIG. 2B, the degree of the rotation of the legs relative to frame 112, in this case less than 90° from the closed configuration, is defined by a difference in length between leg sets 136 and 138, respectively. Also as shown, the respective lengths of each of legs 136a and 138a of the first leg set define an angle [A], at which module 110 is positioned relative to the plane of surface S. Likewise, the respective lengths of each of legs 136b and 138b of the second leg set defines an angle at which module 110 is positioned relative to the plane of surface S. Advantageously, the angle defined by the second leg set is also angle [A].

Grounding wire 122 is shown extending from module 110, is electrically connected to grounding rod 123 which grounding rod may be a copper pipe or metallic rod extending partially beneath and in electrical or galvanic contact with surface S.

FIG. 2A illustrates the view of solar power unit 100 in an operational configuration as seen from the rear. Accordingly, legs 136 can be seen connected by cross bar 137 and mounted to frame 112 by respective hinge pins 134. Advantageously, legs 136 and 138 may be designed to lock into place at the proper angle, such as wherein each of feet 142 are simultaneously parallel to a surface S.

Moreover, grounding rods 123 may serve both the function of electrical grounding as well as for physical anchoring of solar power unit 100 to surface S. Additionally, legs 136 and 138 may individually or both be provided with contact points 140 which may serve to physically attach solar power unit 100 to further units, or contact points 140 may serve additionally as electrical contacts providing electrical contact to an output of junction box/micro-inverter 120.

In operation, the respective lengths of the legs 136 and 138 of the first and second leg sets define an angle which is ideally as close to perpendicular as possible with respect to the average angle of rays of incoming sunlight R as shown in FIG. 2B, with the result that solar cells on front surface 116 exposed to the solar radiation may convert a portion of the light into electrical power, the electricity being conducted to junction box/micro-inverter 120, for conduction away from solar power unit 100 to the load. Angle A may be advantageously adjusted by changing the relative length of legs 136 with respect to 138, in this way altering the angle defined by each of the first and second leg set.

In this connection, the extension of the respective leg sets may be adjustable, legs 136 and/or 138 being provided, for example with telescoping extensions, or similar means for providing adjustable lengths thereof. This is particularly advantageous for adjusting angle A to compensate for seasonal or geographical changes in solar orientation, or to provide adjustability in case surface S is not level. Additionally, individual adjustability of the lengths of each of legs 136 and/or 138 to each other may be advantageous where surface S is not flat, the unevenness being compensable by adjustments, for example extending one of legs 138 further than the other where necessary to stabilize solar power unit 100 on surface S by maintaining the same angle [A] for each of the first and second leg sets. Note that, for embodiments where the solar module does not include a metal frame around the glass laminate, the legs and hinges may be affixed directly to the edge of the laminate, by fasteners, adhesives or another bonding technique.

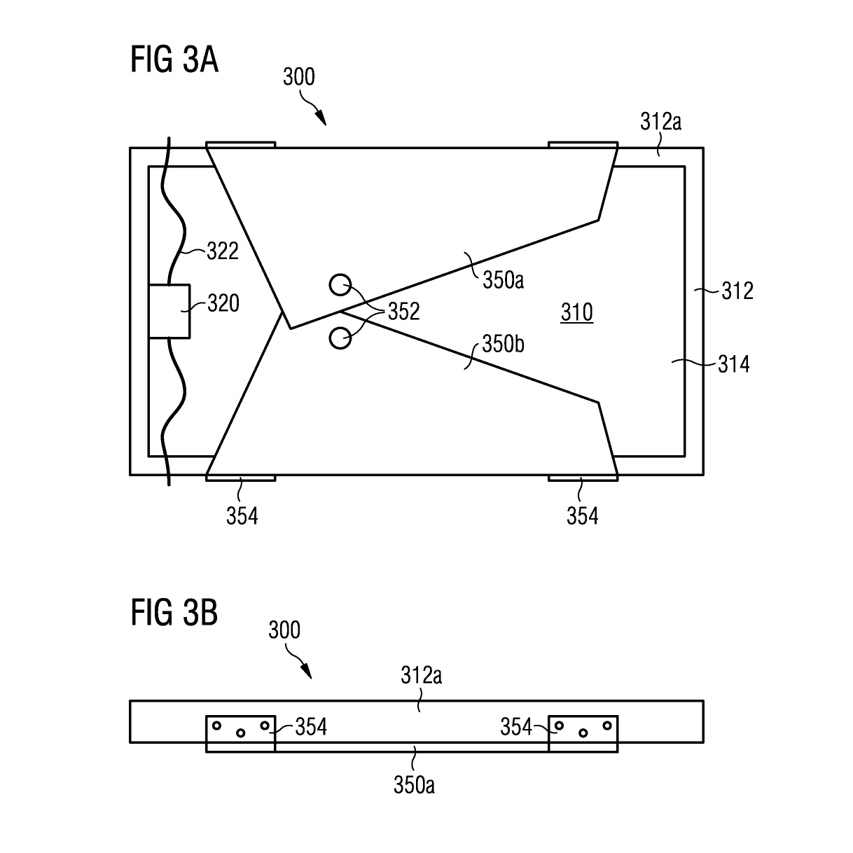

FIGS. 3A and 3B illustrate an alternate embodiment of a self-contained solar power unit. In particular, solar power unit 300 is shown formed around solar module 310. More particularly, and as described in connection with the embodiment of FIGS. 1 and 2 above, solar module 310 may be any conventionally constructed solar module typically comprising back sheet 314 coincident with a solar collection area defined by a rectangular frame 312 that support the back sheet. Likewise, junction box/micro-inverter 320 may be fixed to frame 312 and/or back sheet 314, junction box/micro-inverter 320 having ground wire 322 extending therefrom.

FIG. 3A shows solar power unit 300 from the rear side, i.e. the side facing away from the solar cells of solar module 310. Legs 350a-b, formed for example of sheet material, are shown attached to frame 312, more particularly long side 312a of frame 312, via hinges 354. The hinges may be standard pin hinges or any similar hinging which permits movement of legs 350a-b, preferably about an axis parallel and adjacent to long side 312a of frame 312. FIG. 3B illustrates the mounting of hinges 354 in greater detail. Advantageously, legs 350a-b may be provided with holes 352.

As shown in FIGS. 3A and 3B, solar power unit 300 is illustrated in a flat, closed, or shipping configuration in which solar power unit 300 may for example be stored using a minimum of space. Moreover, in such a configuration, the packing material needed for shipping would be reduced, and legs 350a-b would simultaneously be protected from damage and provide additional protection to the back side of solar module 310. Moreover, as with the embodiment illustrated in FIG. 1, multiple solar power units 300 may be stored for example in a stacked orientation, again occupying a minimum of space.

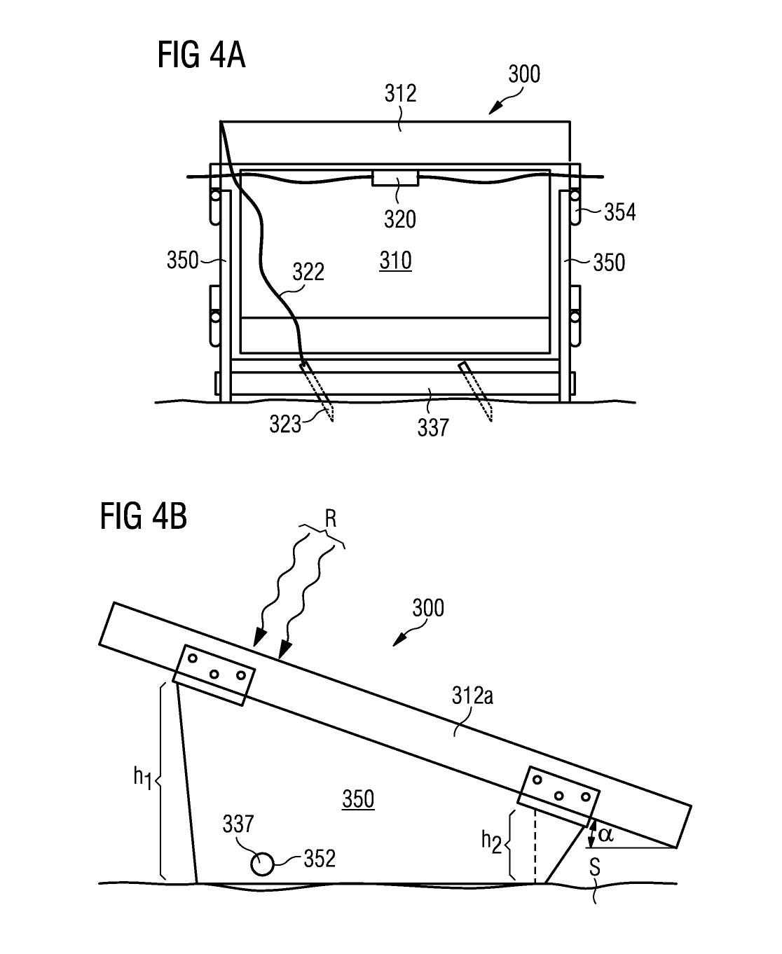

FIGS. 4a and 4b illustrate solar power unit 300 in an operating configuration. In particular, legs 350a-b are shown swung out at 90° to solar module 310, i.e. approximately flush with the side of frame 312. Support rod 337 is shown inserted within and across holes 352 in each of legs 350. Grounding rods 323 are illustrated adjacent to support rod 337, the support rods advantageously providing grounding when inserted for example into surface S, ground wire 322 being electrically connected thereto.

Legs 350a-b are each shown cut in a roughly convex quadrilateral shape, the angle thereof advantageously orienting module 310 at angle [A] relative to surface S. In this sense, it is understood that each of legs 350a and 350b are formed for example as a quadrilateral having a first upper height (h1) and a second, lower height (h2), leg 350a defines a “leg set” for purposes of this disclosure, despite being a unitary structure. Likewise, leg 350b defines a second leg set. These ‘leg sets’ as shown are made of sheet material, such as metal, wood or durable plastic. For weight and/or cost savings, the leg set may not be a solid sheet, but may have cut-outs in various configurations designed to retain strength and stiffness.

During operation, solar radiation R impinges upon the surface of module 310, accordingly angle [A] is advantageously calculated to orient module 310 as closely as possible to perpendicular to the time-averaged direction of the solar radiation. As leg sets 350a-b may be formed of solid material in sheet form such as sheet steel, aluminum, plastic or possibly wood, adjustability in angle A may be effected by trimming one or more sides of legs 350. Advantageously, for example, legs 350 may come pre-marked with cutting lines appropriate for various surface inclinations, and for the geographical latitude at which and/or season during which solar power unit 300 will be used. Alternately, different angles may be manufactured at the factory and delivered to outlets and customers based on geographic location.

The relative orientation of legs 350a-b relative to each other is stabilized by support rod 337 which may be provided with notches or grooves at its ends to securely receive the thickness of the sheet material forming legs 350 and prevent rotation or movement of either leg relative to module 310. Moreover, grounding rods 323 may engage support rod 337 for purposes of further stabilizing solar power unit 300 in addition to providing electrical grounding.

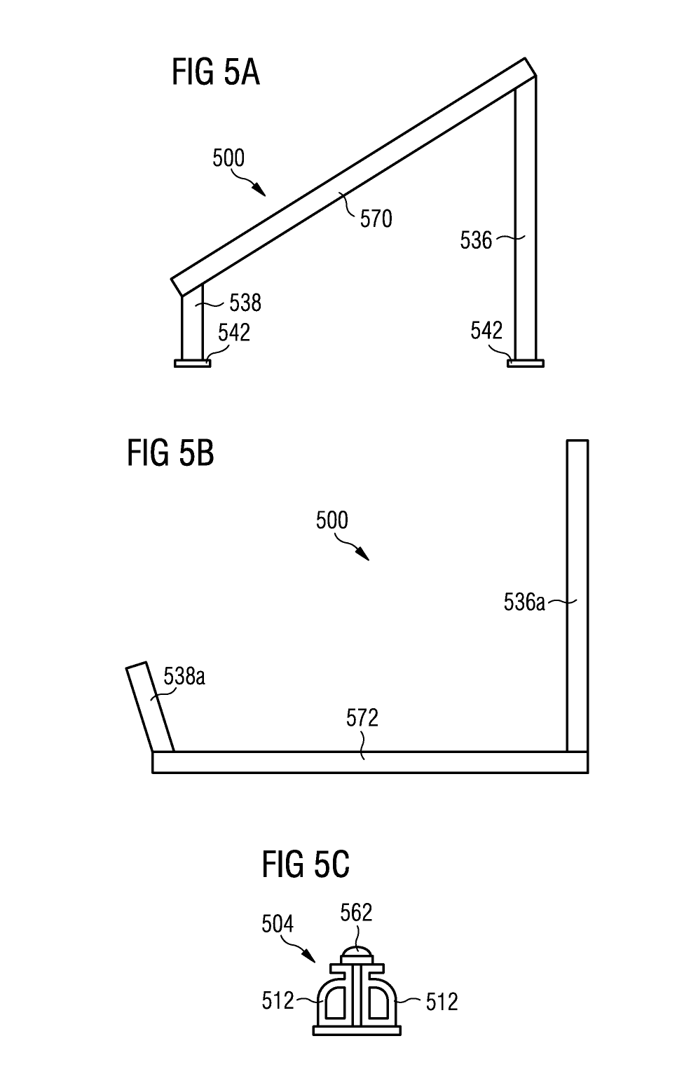

FIG. 5A illustrates an alternative embodiment for support of a solar module in connection with the construction of a solar power unit of the present disclosure. The first leg 538 having a foot 542 and a second, longer leg 536 having a second foot 542 are shown generally parallel to one another and connected to each other at their top by support 570. As assembled, support 500 may be used in combination with similar supports to hold one or more solar modules in place.

Legs 536 and 538 define an angle relative to a planar surface on which they are placed. This angle (which may be angle [A]) defines the orientation of a solar module supported by it. In this sense, legs 536 and 538 together define a leg set for purposes of this disclosure, the leg set being an integral part of support 500.

For example, FIG. 6 illustrates support 500 in operation supporting a plurality of solar modules 610, each shown with solar cells 615 exposed facing forward. More particularly, lengthwise supports 500a and 500b are shown supporting solar module 610a in module array 600. The addition of support 500c enables solar module 610b to be supported between support 500b and 500c. Likewise, support 500d supports module 610c between support 500d and support 500c. Advantageously, each additional module to be supported in array 600 requires only a single additional support 500. Moreover, as in previous embodiments, grounding rods 623 may provide electrical grounding connection for ground wire 622, in addition to providing stabilization and/or support for respective legs 538 and 536, respectively.

FIG. 5B shows an alternate embodiment of an individual support, wherein a leg set includes a first support leg 538a and a second, longer support 536a. The legs are connected together by a lower support brace 572. In this configuration, a solar module may be extended across 538a and 536a. As in FIG. 5A, the difference in leg length between 538a and 536a defines the angle at which solar modules are supported by support structure 502.

FIG. 5c discloses a screw-down retainer that may be attached to, or form an integral part of, for example support 570 of structure 500. As shown, a cross section of frame 512 of one or two solar modules may be secured in place by screw 562.

FIG. 7 illustrates an alternative embodiment of a support for a solar module in connection with the assembly of a solar power unit of the present disclosure. In particular, short direction cross-wise support 700 is shown defining a leg set having leg 738 with foot 742 and a second, longer, leg 736 also with a foot 742 arranged vertically and parallel to each other. Support member 770 extends from the top of leg 738 to the top of leg 736 at an angle defined by the difference in height and distance between the legs. Retainer 704, which may be a screw-down retainer, is shown holding a section of frame 712 in cross-section.

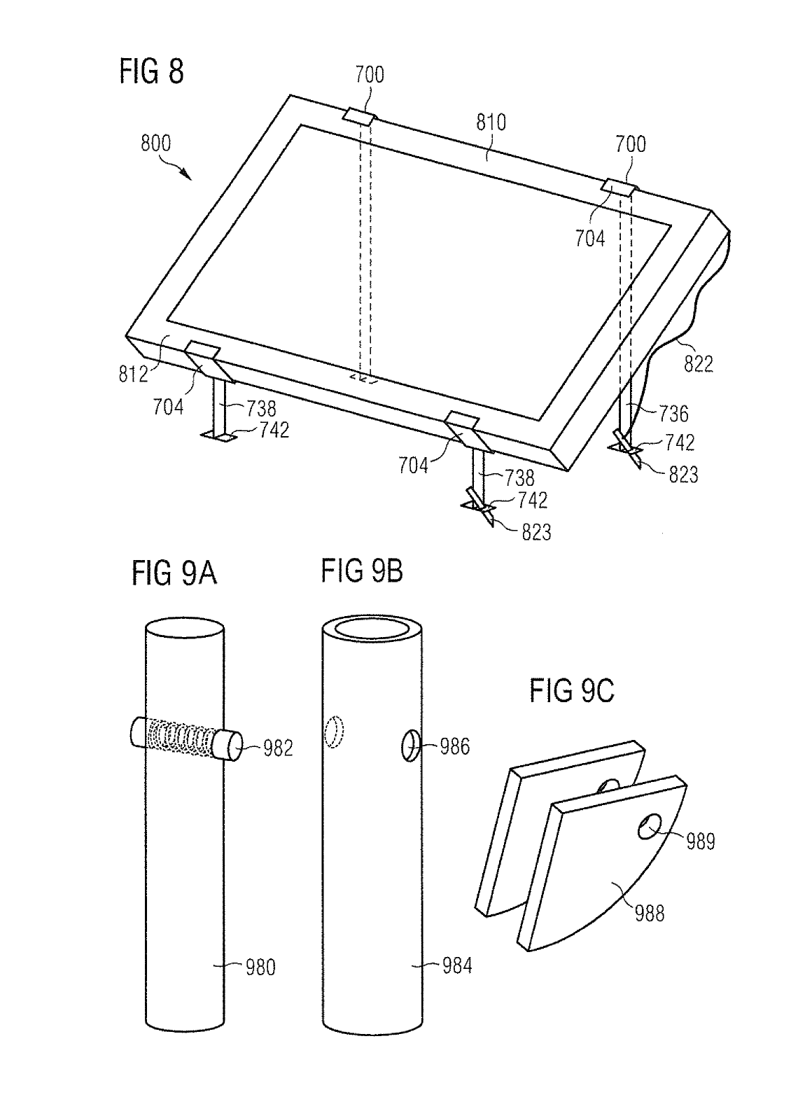

FIG. 8 illustrates solar power unit 800 incorporating supports 700 of FIG. 7. More particularly, frame 812 is shown clamped within retainers 704 in a lengthwise orientation. As in the embodiment shown in FIG. 6, legs 738 and 736 are shown holding module 810 at an angle defined by the difference in height of leg 738 and 736. Also likewise, grounding cable 822 is shown connected to grounding rods 823, wherein the grounding rods may simultaneously provide electrical grounding and structural support for solar power unit 800 in the configuration with support 700 shown.

As disclosed above, in particular with respect to embodiments disclosing discreet leg structures such as in FIGS. 2 and FIGS. 5-8, specific leg structures enabling adjustable leg heights are disclosed in FIG. 9. In particular, rod 980 is provided with spring loaded buttons which engage holes such as holes 986 in pole 984. For example, pole 984 is advantageously a hollow tube or pipe, with an inner diameter sufficient to receive rod 980. Spring loaded buttons 982 may be depressed, such as by hand, and inserted within tube 984 until buttons 982 engage holes 986 snapping into place and holding the components longitudinally and rotationally relative to each other. Multiple holes 986 therefore would permit various degrees of extension/leg length and provide the possibility of varying leg height, such as to change the angle of the solar module of the solar power unit of the present disclosure. Alternately, a hinge 988 having holes 989 may perform similarly, wherein rotation about an axis, i.e. such as in the lowering of one or more legs from the closed or shipping position into the open or operating position, may be achieved whereby rod 980 having spring loaded buttons 982 may rotate about an axis until the spring loaded buttons engage holes 989 thereby locking the legs in place. Again multiple holes 989 may be provided with the result that the angle of leg extension may be variably set.

The embodiments of the present disclosure, variously described above, may be produced at low price points and may be marketed directly to a consumer, with the result that a professional installer, and associated expense, is not necessarily required to enable a consumer use solar power, including at appropriate mains voltages. One or more of the solar power units variously described herein may be sold commercially in stores marketing appliances and/or electronics, and may be sold in single unit packaging for use alone, or for addition into an array of several units.

Complexity of installation is minimized by advantageously facilitating ground-mounting such as in a yard, an allocation of space similar to a typical vegetable garden. Moreover, although a solar module may be purpose-designed to function with the solar power units disclosed herein, the incorporation of existing solar modules may offer advantages, particularly in terms of standardization, or utilization in conjunction with larger fixed installations.

Legs and other support components may be shipped with the solar module, either pre-installed on the module prior to shipping, or by the end user. Even where already attached, such as to the frame of the solar module, the legs and other support components may be shipped flat, removed upon delivery, and snapped into place, staked into the ground, and/or wiring to adjacent units.

Each of the above embodiments may include side brackets that may also include electrical contacts for purposes of securing units to one another physically and electrically. Contact points 140 of FIG. 2 are exemplary, and may be included on any embodiment of this disclosure, with similar results.

The solar power units may have a cabling arrangement with both the additive junction box connection and the return line being found on each module, allowing the power to be taken out of one end by an outdoor grade extension cord (such as a ground-fault circuit interrupter enabled outdoor extension, optionally protected by a PVC tube) sold at a standard length. In this sense, the wiring may be similar in some aspects to outdoor lighting.

The angle of incline for the module may be varied by the height of a snap-up strut on the high, or low, side of the solar module, and differently angled products could be sold at stores in different latitudes, or for differently inclined installation surfaces.

Each of the solar power units may be staked to the ground, possibly accomplishing electrical grounding and physical securement in a single step. A user thus has the flexibility to pick a sunny spot and point the array (or individual module) in the optimal direction, with the net effect being similar to a garden patch for harvesting sunlight.

Because of the AC power, the use of the extension cord may be no different than handling other power cords/plugs in a house. The AC micro-inverters may be configured not to deliver power through the cables until grid power is recognized, sometime after they are plugged in, and will stop power delivery if connection to the grid is lost.

The end of a cord connecting the panel to the house can be a standard 110/220V cable, and may plug directly into a house outlet. Alternatively, it may be wired directly into a circuit breaker box.

While the embodiments of the present disclosure have been particularly shown and described with reference to the drawings and the description herein, it should be understood by those skilled in the art that various changes in details of the form may be made therein without departing from the spirit and scope of the invention as defined by the appended claims. The scope of the invention is thus indicated by the appended claims and all changes which come within the meaning and range of equivalency of the claims are therefore intended to be embraced.

1. A solar power unit comprising:
a solar module comprising:
a frame defining a planar solar collection area,
a photovoltaic cell mounted within said area,
a junction box electrically connected to at least one of said photovoltaic cells; and
a support structure fixable to said solar module having a first leg set comprising a first upper leg and a first lower leg, the leg set securing the solar module on a surface at an angle.

2. The solar power unit of claim 1, further comprising at least one first hinge for fixing the first leg set to the solar module.

3. The solar power unit of claim 2, wherein the first leg set may rotate on said first hinge on a first axis parallel to a first side of said frame.

4. The solar power unit of claim 3, wherein the support structure further comprises a second leg set comprising a second upper leg and a second lower leg, the second leg set securing the solar module at said angle.

5. The solar power unit of claim 4, further comprising at least one second hinge for fixing the second leg set to the solar module.

6. The solar power unit of claim 5, wherein the second leg set may rotate on said second hinge on a second axis parallel to said first axis, and to a second side of said frame.

7. The solar power unit of claim 6 wherein the first and second leg sets may respectively be rotated on the first and second axes until said legs are oriented in parallel with the plane of said solar collection area.

8. The solar power unit of claim 6 wherein the first and second leg sets may respectively be rotated on the first and second axes until said legs are oriented perpendicular to the plane of said solar collection area.

9. The solar power unit of claim 1 further including a micro-inverter connected to or incorporated in said junction box.

10. The solar power unit of claim 6 further including means for providing electrical soil grounding, said means engaging at least one of said first and second leg sets for securing the same to a soil surface.

11. A self-contained solar power unit comprising:
a solar module comprising:
a frame defining a planar solar collection area,
a photovoltaic cell mounted within said area,
a junction box electrically connected to at least one of said photovoltaic cells; and
a support structure rotatably hinged to said solar module having a first leg set comprising a first upper leg height and a first lower leg height, and
a second leg set comprising a second upper leg height and a second lower leg height, the first and second leg sets securing the solar module on a surface at an angle.

12. The self-contained solar power unit of claim 11 wherein each of said first and second leg sets is a unitary structure.

13. The self-contained solar power unit of claim 12 wherein each of said first and second leg sets has a generally convex quadrilateral shape, defined by a first height corresponding to one of said first and second upper leg height and a second height corresponding to one of said first and second lower leg height, respectively.

14. The self-contained solar power unit of claim 12 wherein said first and second upper leg height are the same, and wherein said first and second lower leg height are the same.

15. The self-contained solar power unit of claim 11 further comprising a connector for electrically linking said solar power unit to a second solar power unit.

16. The self-contained solar power unit of claim 15 further comprising a micro inverter.

17. The self-contained solar power unit of claim 13 wherein each of said first and second leg sets includes a securing port for receiving a means for fixing the first and second leg sets to each other.

18. The self-contained solar power unit of claim 11 wherein said first and second leg set may be folded parallel with said planar solar collection area.

19. The self-contained solar power unit of claim 11 wherein said angle is adjustable.

20. The self-contained solar power unit of claim 11 wherein the legs fold up and snap into place.
